(19) United States
(12) Patent Application Publication
(10) Pub. No.: US 2023/0030962 A1
(43) Pub. Date: Feb. 2, 2023

(54) SYSTEM AND METHOD FOR GENERATING AN OPTICAL SIGNAL

(71) Applicant: Mellanox Technologies, Ltd., Yokneam (IL)

(72) Inventors: Itshak Kalifa, Bat Yam (IL); Elad Mentovich, Tel Aviv (IL)

(21) Appl. No.: 17/876,245

(22) Filed: Jul. 28, 2022

Related U.S. Application Data
(60) Provisional application No. 63/227,650, filed on Jul. 30, 2021.

(51) Int. Cl. H01S 5/42; H01S 5/183; H01S 5/026; H01S 5/40

(52) U.S. Cl. CPC H01S 5/423; H01S 5/18308; H01S 5/0261; H01S 5/4012

(57) ABSTRACT

To address the need to excite lasers at a high frequency while minimizing electrical parasitic components, the present invention embraces a system and method of exciting a laser using a direct injection of an electron beam. The system may include a low voltage electron emission device made of one or more electron sources. When the device is activated, an electrical field is applied to the tip of each electron source, causing the electron source to emit a stream of electrons. The electrons are directed into a VCSEL, causing it to emit an optical signal. In another aspect, a system for random number generation is provided. The system may also include a processor that receives a measurement of an initial random value, executes an algorithm, where at least one input of the algorithm is the initial random value, and determines a final random value.

### CROSS-REFERENCE TO RELATED APPLICATIONS

This application claims the benefit of U.S. Provisional Patent Application Ser. No. 63/227,650, filed Jul. 30, 2021, entitled “VCSEL-Based Extended Data Rate Solutions: Field Emission VCSEL,” the entirety of which is incorporated herein by reference.

### FIELD OF THE INVENTION

The present invention relates to systems and methods for reducing parasitics in an optoelectronic system.

### BACKGROUND

In the field of fiber optic communications, a light source or laser converts electrical signals into optical signals. This may be achieved by electrical pumping, wherein an electric current from a circuit is used to excite the laser, causing it to emit light at a particular wavelength (the optical signal). This optical signal is then transmitted through a fiber optic cable to a transceiver. Fiber optic cables can range in length from less than one meter to almost 100 kilometers depending on where the data is being transmitted. Once the optical signal reaches a transceiver, the transceiver converts the optical signal back into an electrical data signal for downstream use or processing.

Internet traffic over fiber optic cables continues to increase, resulting in an increased demand for a higher data transfer rate, or bandwidth, between components. Typically, the bandwidth of VCSELs is limited by the presence of electrical parasitic components, which are inherent in every electrical circuit and create less than ideal electrical behavior. For example, a resistor in a circuit will always have a small, inherent capacitance value that reduces its resistance value. This capacitance value is considered a parasitic component.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

Accordingly, embodiments of the present disclosure provide a system for generating optical signals. The system may include a vertical-cavity surface-emitting laser (VCSEL) configured to emit an optical signal; and a low voltage electron emission device operatively coupled to the VCSEL and including an electron source. Upon activation of the low voltage electron emission device, the electron source is configured to emit a stream of electrons, and the VCSEL is configured to receive the stream of electrons from the low voltage electron emission device. The VCSEL is configured to emit an optical signal in response to receipt of the stream of electrons.

In some embodiments, the VCSEL is one of a plurality of VCSELs, where the low voltage electron emission device includes an array of electron sources, and each electron source is configured to be operatively coupled to one VCSEL from the plurality of VCSELs.

In some embodiments, the VCSEL is one of a plurality of VCSELs, where the low voltage electron emission device includes a plurality of ring-shaped arrays of electron sources, and each ring-shaped array is configured to be operatively coupled to one VCSEL from the plurality of VCSELs.

In some embodiments, the electron source includes a carbon nanotube.

In some embodiments, the low voltage electron emission device is operatively coupled to a direct current (DC) power source, and the DC power source is configured to apply a voltage of less than five volts to the low voltage electron emission device to generate the stream of electrons.

In some embodiments, the electron source includes a metallic tip.

In some embodiments, the activation of the low voltage electron emission device causes an electrical field to be applied around the electron source, causing the electron source to emit electrons.

In some embodiments, the low voltage electron emission device further includes a gate configured to focus the stream of electrons into a collimated electron beam.

In some embodiments, the VCSEL includes an input end and an emission end, where the gate is further configured to direct the electron beam into the input end of the VCSEL and where the optical signal is emitted from the emission end of the VCSEL.

In some embodiments, the VCSEL includes an input end and an emission end, where the gate is further configured to operate as an external cavity resonator and the optical signal is emitted from the emission end of the VCSEL.

In some embodiments, the system further includes a processor operatively coupled to the low voltage electron emission device, where the processor is configured to determine a random output value based on a measurement of an initial random value obtained from at least one of the stream of electrons or the optical signal.

Embodiments of the present disclosure may also provide a system for random number generation. As such, the system may include a low voltage electron emission device including a carbon nanotube. Upon activation of the low voltage electron emission device, the carbon nanotube is configured to emit a stream of electrons. The system may further include a processor. The processor may be configured to: receive a measurement of at least one initial random value obtained from at least one of the stream of electrons or an optical signal; execute an algorithm, where at least one input of the algorithm is the at least one initial random value; and determine, based on an output of the algorithm, a final random value.

In some embodiments, the system further includes a measuring device configured to obtain the measurement of the initial random value and to communicate the initial random value to the processor. The measuring device may include at least a photodiode amplifier and a clock.

In some embodiments, the initial random value includes at least a timestamp associated with a photon.

In some embodiments, the algorithm is a true random number generating (TRNG) algorithm.

In some embodiments, the final random value includes at least one of: a nonce, a cryptographic key, a numeric value, a hash string, or a string value comprising a combination of alphanumeric values.

In some embodiments, the system further includes a vertical-cavity surface-emitting laser (VCSEL) operatively coupled to the low voltage electron emission device. The VCSEL may be configured to receive the stream of electrons from the low voltage electron emission device and to emit the optical signal in response to receipt of the stream of electrons.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made the accompanying drawings, wherein:

FIG. 1 illustrates a system environment for generating optical signals, in accordance with an embodiment of the present invention;

FIG. 2 is a cross-sectional view of an electric field generator for use in a system for generating optical signals, in accordance with an embodiment of the present invention;

FIGS. 3A and 3B illustrate an array of electron sources, in accordance with an embodiment of the present invention;

FIGS. 3C-1 and 3C-2 illustrate a ring-shaped array of electron sources, in accordance with an embodiment of the present invention;

FIG. 4 illustrates a system environment for random number generation, in accordance with an embodiment of the present invention;

FIG. 5 illustrates a method for generating optical signals, in accordance with an embodiment of the invention; and

FIG. 6 illustrates a method for generating random numbers, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on.” Like numbers refer to like elements throughout.

As noted, in the field of fiber optic communications, a light source or laser converts electrical signals into optical signals, which are then used to transmit data. Vertical-cavity surface-emitting lasers (VCSELs) are preferred for this application because they emit light beams that are perpendicular to the laser's surface. This allows a high density of VCSELs to be packaged together into small, two-dimensional arrays. These laser arrays have a smaller physical footprint than an array of traditional, edge-emitting lasers. In addition, VCSELs create circular light beams that are particularly well suited for connection to circular optical fibers.

Typically, optical signals generated by VCSELs are transmitted through fiber optic cables to downstream transceivers. The transceivers then convert the optical signals back into electrical data signals for downstream use or processing. Internet traffic over fiber optic cables continues to increase, resulting in an increased demand for a higher data transfer rate, or bandwidth, between components.

Electrical pumping is a known method of generating optical signals. Electrical pumping entails using an electric current from a circuit, or an applied voltage, to excite a VCSEL, thereby causing the VCSEL to emit light at a particular wavelength (the optical signal). Typically, the bandwidth of VCSELs is limited by the presence of electrical parasitic components, which are inherent in every electrical circuit and create a difference between ideal electrical behavior and real-world conditions. For example, a resistor in a circuit will always have a small, inherent capacitance value that reduces its resistance value. This capacitance value is considered a parasitic component. Although parasitic components can be considered when designing lower-frequency circuits, the effects of parasitic components are magnified as the frequency, or bandwidth, of a circuit increases. Therefore, even a highly optimized circuit design will always impose some limit on a VCSEL's potential bandwidth. To address this limitation, there is a need for a method of exciting VCSELs that does not require electrical pumping.

Embodiments of the present invention are thus directed to novel systems and methods for exciting VCSELs without the use of an applied electric current. Instead, a VCSEL is excited via direct injection of an electron beam. Because electrical pumping is not used to stimulate the VCSEL, the effect of parasitic components is greatly reduced and the VCSEL can be operated at higher frequencies. An electron beam may be generated by a low voltage electron emission device comprised of one or more electron sources such a carbon nanotubes. When the device is activated, an electrical field is applied to the tip of each electron source, causing the electron source to emit a stream of electrons. In some embodiments, a gate is used to focus the stream of electrons into a beam that is directed into a VCSEL, causing it to emit an optical signal, as will be described in greater detail below and with reference to the figures.

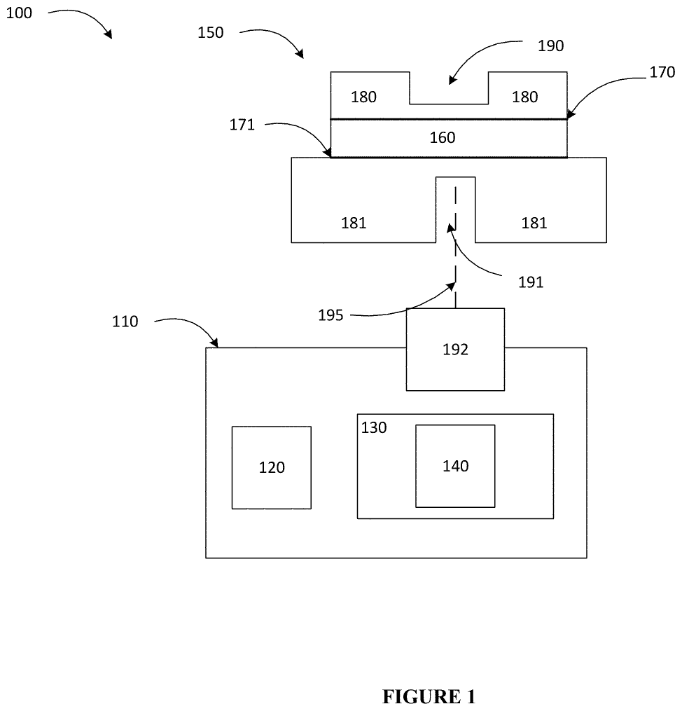

FIG. 1 illustrates a system environment 100 for generating optical signals, in accordance with one embodiment of the present invention. In particular, FIG. 1 illustrates a low voltage election emission device 110 that is operatively coupled to a laser 150. In some embodiments, the laser 150 may be a vertical-cavity surface-emitting laser (VCSEL) 150. For ease of explanation, the term VCSEL is used throughout, although the uses of other types of lasers may be within the scope of the invention. In such a configuration, the low voltage election emission device 110 may be configured to emit a stream of electrons and the VCSEL 150 may be configured to receive the stream of the electrons. In some embodiments, the low voltage election emission device 110 and the VCSEL 150 may be mechanically or electrically coupled. Additionally or alternatively, the VCSEL 150 may be a fully integrated component of the low voltage election emission device 110. The system 100 may further include a control device (not shown), such as a processor or programmable logic controller (PLC), that may be operatively coupled to the low voltage election emission device 110 or may be a fully integrated component of the low voltage election emission device 110. The control device may be configured to control activation of the low voltage election emission device 110 based on a control signal.

The low voltage election emission device 110 may comprise a power source 120, an electric field generator 130, and at least one electron source 140. Generally, the power source 120 may be a device that supplies electrical energy to an electrical load. In a preferred embodiment, the power source 120 may be a direct current (DC) power source, although other types of power sources may be used. The power source 120 may be operatively coupled to the electric field generator 130 to supply the electric field generator 130 with electrical energy, or an applied voltage. In order to achieve a usable laser bandwidth for optical communications, the applied voltage may be low, ranging, for example, up to 5V. In a preferred embodiment, the applied voltage may range from 2V to 2.5V. In some embodiments, the control device (not shown) may be operatively coupled to the power source 120 and may control operation and/or activation of the power source 120.

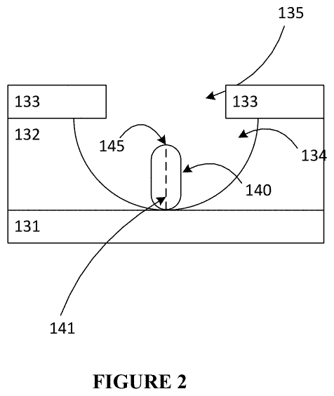

The electric field generator 130 may comprise any device capable of producing an electrical field when provided with an applied voltage as is described further with respect to FIG. 2. In some embodiments, the control device may be operatively coupled to the electric field generator 130 and may control operation and/or activation of the electric field generator 130 as is described further with reference to FIG. 2.

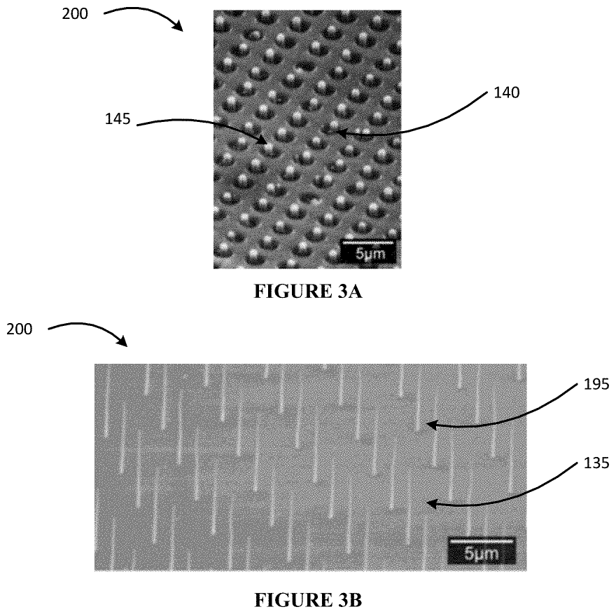

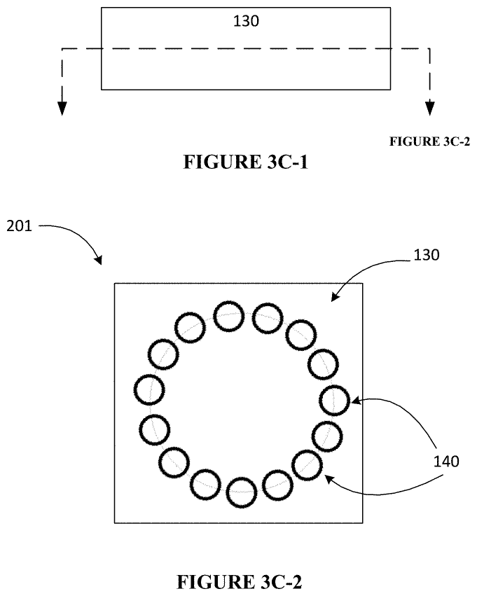

The at least one electron source 140 may comprise any molecule capable of emitting a stream of electrons 195 when under the influence of an electric field, such as a metallic molecule. In some embodiments, the at least one electron source may comprise a carbon nanotube (CNT). The electron source 140 may be operatively coupled to the electric field generator 130 as is described in greater detail with respect to FIG. 2. The electron source 140 may be shaped as a capsule, cylinder, tube, rod, or the like and may comprise a longitudinal axis 141 and a distal end, or metallic tip 145. In some embodiments, the low voltage election emission device 110 may comprise an array of electron sources 140. The electron sources 140 in the array may be arranged such that the longitudinal axes 141 are parallel to each other, as shown in and further described with reference to FIGS. 3A and 3B.

As noted above, the laser 150 may comprise a vertical-cavity surface-emitting laser (VCSEL) configured to receive the stream of electrons 195 from the low voltage election emission device 110 and to emit an optical signal in response. In this regard, the VCSEL 150 may comprise a laser cavity or gain region 160, oxide layers 170 and 171, a top mirror 180, a bottom mirror 181, a beam aperture 190, and an electron aperture 191. The electron aperture 191, or input end, may comprise an opening in the VCSEL 150 configured to accept the stream of electrons and to direct the stream of electrons into the gain region 160. The gain region 160 may comprise a plurality of quantum wells configured to generate light that travels between the top mirror 180 and the bottom mirror 181 in a lasing process. In some embodiments, the bottom mirror 181 may be more reflective than the top mirror 180, causing the light in the gain region 160 to be directed upwards and out of the beam aperture 190. The top mirror 180 and bottom mirror 181 may be configured to produce an optical signal at a particular wavelength. The oxide layers 170 and 171 may be configured to confine the light within the gain region 160 during the lasing process, as would be understood by one skilled in the art in view of the present disclosure. The beam aperture 190, or emission end, may comprise an opening in the VCSEL 150 configured to receive light from the gain region 160 and emit the light as a beam. In some embodiments, the beam aperture 190 may have a circular cross-section configured to create a circular light beam for connection to an optical fiber (not shown). In some embodiments, the system 100 may comprise an array of lasers 150 as is further described with reference to FIG. 3A.

The system 100 may further comprise a gate 192 operatively coupled to the low voltage election emission device 110 and the VCSEL 150. Additionally or alternatively, the gate 192 may be a fully integrated component of the low voltage election emission device 110 or the VCSEL 150. The gate 192 may comprise a dielectric material such as silicon dioxide and may be configured to contain and accumulate electrons emitted from the at least one electron source 140 such that the emitted electrons may be focused into a single stream for injection into the VCSEL 150. As such, the gate 192 may be further configured to direct the stream of electrons into the electron aperture 191 of the VCSEL 150. The gate 192 may be operatively coupled to the control device such that the control device may control the opening and/or closing of the gate 192, thereby controlling the size of the emitted stream of electrons. In some embodiments, opening and/or closing of the gate 192 may be achieved via application of an electrostatic field. The dimensions of the gate 192 and the distance between the gate 192 and the electron aperture 191 may be selected such that the gate 192 operates as an external cavity resonator, thereby increasing the bandwidth of the VCSEL 150. The embodiment of the system environment illustrated in FIG. 1 is exemplary and other embodiments may vary.

FIG. 2 illustrates a cross-sectional view of the electric field generator 130, in accordance with an embodiment of the present invention. As described with in reference to FIG. 1, the electric field generator 130 may comprise any device capable of producing an electrical field when provided with an applied voltage. In some embodiments, the electric field generator 130 may comprise a base layer 131, and intermediate layer 132, and a top gate 133. The base layer 131 may be comprised of a silicon-based material, and the intermediate layer 132 may be comprised of silicon dioxide. The intermediate layer 132 may further comprise an intermediate aperture 134. For example, the intermediate aperture 134 may be a hemispherical or bowl-shaped void that is formed in the intermediate layer 132. In some embodiments, the electron source 140 may be operatively coupled to the base layer 131 and may be positioned within the intermediate aperture 134 such that the electron source 140 does not come into contact with the intermediate layer 132. The top gate 133 may be comprised of a polysilicon-based material and may comprise a top aperture 135. The top aperture 135 may be aligned with the intermediate aperture 134. In some cases, the top aperture 135 may be smaller than an adjacent portion of the intermediate aperture 134, such that the top aperture is aligned with a central portion of the intermediate aperture and the top gate 133 covers a peripheral portion of the intermediate aperture.

In some embodiments, the control device may be operatively coupled to the electric field generator 130 and may control operation and/or activation of the electric field generator 130 as is described further with reference to FIG. 2. When activated, the base layer 131 and top gate 133 of the electric field generator 130 may be separately supplied with an applied voltage from the power source 120. The base layer 131 and top gate 133 may be supplied with slightly different applied voltages, creating an electric field in the intermediate aperture 134. The at least one electron source 140 may be positioned within the intermediate aperture 134 and thus may be positioned within the electric field. Additionally or alternatively, the electric field generator 130 may comprise a plurality of intermediate apertures 134, and each intermediate aperture 134 may contain one of the at least one electron sources 140. In this case, the electric field at each of the plurality of intermediate apertures may be jointly or independently controllable (e.g., via the control device).

The electron source 140 may be operatively coupled to the electric field generator 130. The electron source 140 may be shaped as a capsule, cylinder, tube, rod, or the like and may comprise a longitudinal axis 141 and a distal end, or metallic tip 145. In some embodiments, the low voltage election emission device 110 may comprise an array of electron sources 140. The electron sources 140 in the array may be arranged such that the longitudinal axes 141 are parallel to each other, as shown in and further described with reference to FIGS. 3A and 3B. The embodiment of the electric field generator illustrated in FIG. 2 is exemplary and other embodiments may vary.

As noted above, in some embodiments the electron source 140 may, in some embodiments, comprise an array 200 of electron sources 140, as shown in FIG. 3A. The plurality of electron sources 140 in the array 200 may be arranged such that the longitudinal axes 141 of the electron sources are parallel to each other, and the metallic tips 145 are orientated in the same direction. In accordance with this embodiment, the electric field generator 130 (shown in FIG. 1) may comprise a plurality of intermediate apertures 134 and top gates 135, and each intermediate aperture 134 may contain one of the at least one electron sources 140 of the array 200. The electric field at each of the plurality of intermediate apertures 134 may be jointly or independently controllable.

Additionally or alternatively, the system 100 may comprise an array of VCSELs 150 (not shown), and each VCSEL 150 may be operatively coupled to one of the at least one electron sources 140 of the array 200. Because the plurality of parallel plate capacitors may be independently controllable, each VCSEL 150 may be independently controllable as well. As such, the system may be configured to generate a plurality of simultaneous optical signals. Furthermore, the system 100 may comprise a plurality of gates 192, and each gate 192 may be operatively coupled to one of the at least one electron sources 140 and one of the VCSELs 150.

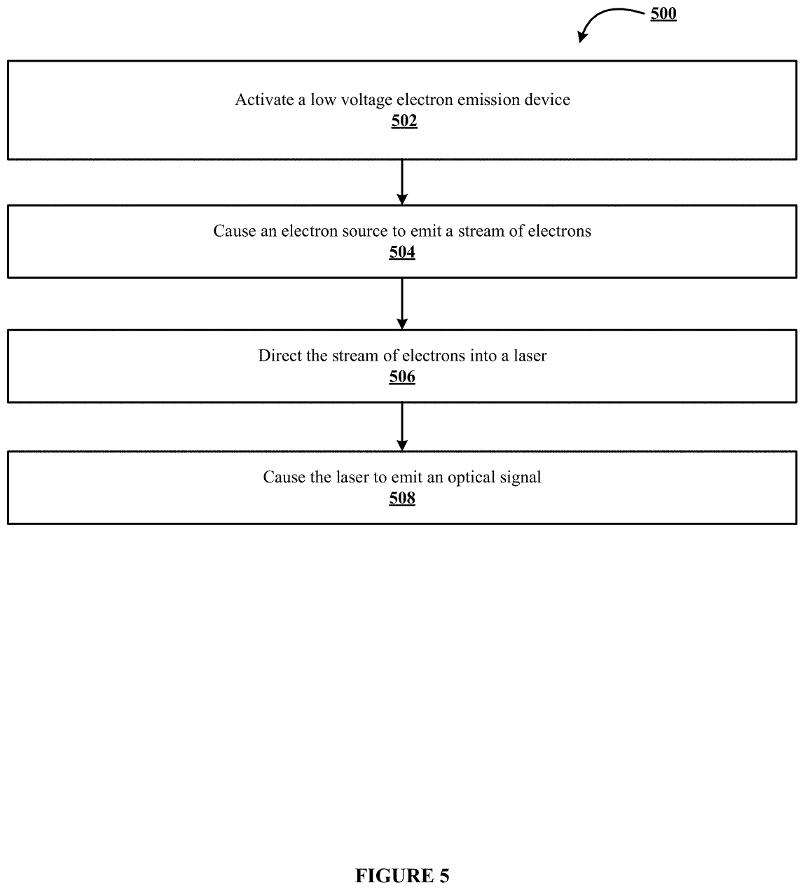

FIG. 3B illustrates an activated array 200 of electron sources 140, in accordance with an embodiment of the invention. As is described in further detail with reference to FIG. 5, the array 200 may be activated when the power source 120 provides an applied voltage to the electric field generator 130. The electric field generator 130 may generate an electric field between the top gate 135 and base layer 131 (shown in FIG. 1), and around the metallic tip 145 of the at least one electron source 140, causing an emission of electrons at each metallic tip 145. Each gate 192 may then focus an emission of electrons 195 into an electron beam.

FIGS. 3C-1 and 3C-2 illustrate another embodiment in which the field generator 130 comprises a ring-shaped array 201 of electron sources 140. In particular, FIG. 3C-2 illustrates a cross-sectional view of the field generator 130 shown in FIG. 3C-1. As shown in FIG. 3C-2, in some embodiments, a plurality of electron sources 140 may be arranged in a ring-shaped array 201, and each ring-shaped array 201 may be operatively coupled to one VCSEL 150 (shown in FIG. 1). In such embodiments, the emission of electrons 195 from each of the plurality of electron sources 140 may be collimated by the gate 192 into the electron aperture 191 of the VCSEL 150 (shown in FIG. 1). Compared to embodiments wherein each VCSEL 150 is coupled to a single electron source 140, each ring-shaped array 201 of electron sources 140 may provide an increased current of electrons into a single VCSEL 150, thus increasing a power output of the VCSEL. In addition, a ring-shaped array 201 of electron sources 140 may more evenly distribute electrons into the electron aperture 191 of the VCSEL 150, resulting in more stable VCSEL performance and reduced distortion of the optical signal.

According to other embodiments of the invention, the system described above may be used for random number generation. Random number generation is an essential component of cryptography and internet security. When information such as passwords, IP addresses, and other data is encrypted by an encryption algorithm, the encryption algorithm uses a random number generator (RNG) to create a key or nonce. If another computing system derives the key, it will be able to decrypt the information. Many conventional encryption algorithms are configured to use pseudo-random number generators, or PRNGs. Although PRNGs produce values that appear random, they are generated by inputting set values, or a seed, into a highly complex algorithm. Thus, if another computing system knows the set input values to that algorithm, it will be able to derive future “random” output values based on past “random” output values. Therefore, there is a need for a true random number generator, or TRNG, which utilizes random input values to derive truly random output values.

Random input values cannot be created by an algorithm and must be obtained from a physical process, such as thermal noise, atmospheric pressure, optical noise, or quantum processes such as electron absorption and emission. Because embodiments of the system 100 described above in connection with FIGS. 1 and 2 use electron emission to produce optical signals, random values may be obtained for use as a one-time use key for transmission of encrypted data.

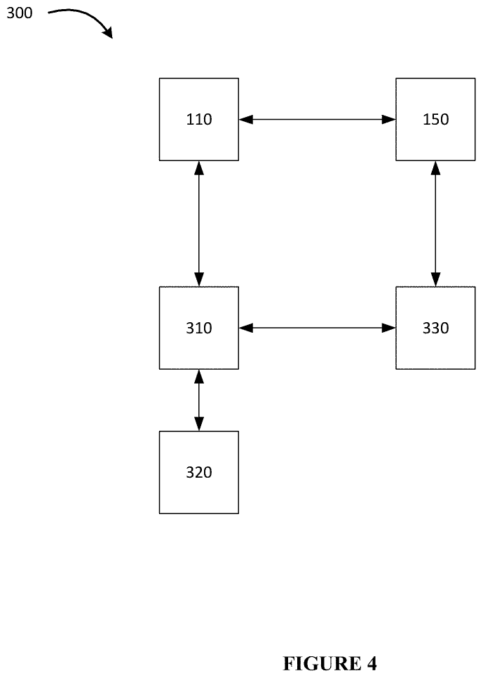

As such, FIG. 4 illustrates a system environment 300 for random number generation, in accordance with an embodiment of the current invention. The system 300 may comprise the low voltage election emission device 110 and the VCSEL 150 of FIG. 1 operatively coupled to a processor 310, a memory device 320, and a measurement device 330. As used herein, the term “processor” generally includes circuitry used for implementing the communication and/or logic functions of the particular system. For example, a processor may include a digital signal processor device, a microprocessor device, and various analog-to-digital converters, digital-to-analog converters, and other support circuits and/or combinations of the foregoing. Control and signal processing functions of the system are allocated between these processing devices according to their respective capabilities. The processor 310 may include functionality to operate one or more software programs based on computer-readable instructions thereof, which may be stored in the memory device 320.

The memory device 320 may be operatively coupled to the processor 310 and may have computer-readable instructions stored thereon. The computer-readable instructions may instruct the processor 310 to perform certain logic, data processing, and data storing functions. Specifically, the computer-readable instructions may cause the processor to receive data from the measurement device 330, execute an algorithm, and/or output a result of the algorithm.

The measurement device 330 may be configured to measure a random value from an optical signal generated by the VCSEL 150, such as a timestamp, temperature, frequency, and/or energy level. As such, the measurement device 330 may comprise any device suitable for detecting said values, such as a thermometer, clock, power sensor, camera, and/or the like. In some embodiments, the measurement device 330 may comprise a photodiode amplifier configured to sense individual photons from the optical signal. Because electron emission may cause random fluctuations in the optical signal, the timestamps associated with individual photons reaching the measurement device 330 may be random values. In some embodiments, the measurement device 330 may be configured to measure a random quantum value from the optical signal and/or the stream of electrons 191. As such, the measurement device 330 may comprise any device suitable for detecting a quantum value, such as a beam splitter, mirror, lens, or the like. The measurement device 330 may be operatively coupled to the processor 310 and may be configured to transmit a measured value to the processor 310. In some embodiments, the measurement device 330 may be a fully integrated component of the processor 310. The embodiments of the system environment 300 illustrated in FIG. 4 is exemplary and other embodiments may vary.

FIG. 5 illustrates a method 400 for generating optical signals, in accordance with an embodiment of the invention. The method may begin at block 402, wherein the low voltage election emission device 110 (shown in FIG. 1) is activated. The low voltage election emission device 110 may be activated in response to a control signal or instruction received from the control device, the processor 310, or another input source. Activation of the low voltage election emission device 100 may cause the power source 120 to begin supplying a voltage to the electric field generator 130. Additionally or alternatively, activation of the low voltage election emission device 110 may comprise sending a digital logic signal to the electric field generator 130, causing the electric field generator 130 to begin generating an electron field at each electron source 140. When activated, the base layer 131 and top gate 133 of the electric field generator 130 may be separately supplied with an applied voltage from the power source 120. The base layer 131 and top gate 133 may be supplied with slightly different applied voltages, creating an electric field in the intermediate aperture 134. The electron source 140 may be positioned within the intermediate aperture 134 such that the electric field surrounds the electron source 140.

The method may then continue to block 404, wherein the electron source 140 is caused to emit a stream of electrons out of the top aperture 135. In some embodiments, the electric field at each metallic electron source 140 may be sufficiently strong to result in electron emission. The required strength of the electric field may thus vary based on a material property of the electron source 140 and/or the shape of the metallic tip 145. As such, the method 400 may be applied to a wide variety of electron source types.

The method may then continue to block 406, wherein the stream of electrons is directed into the VCSEL 150, as described above in connection with FIG. 1. In some embodiments, in which the low voltage election emission device 110 comprises an array of electron sources 140, a plurality of streams of electrons (e.g., one stream being emitted from each respective electron source) may be directed into a corresponding plurality of VCSELs 150. In some embodiments, each stream of electrons may be focused out of the low voltage election emission device 110 and into the VCSEL 150 via a corresponding gate 192. The gate 192 may be controlled by the control device and may collimate the electrons into a unidirectional flow, maximizing the number of electrons that reaches the electron aperture 191 and minimizing the number of electrons that escapes the system environment 100.

The method may then continue to block 408, in which the VCSEL 150 is caused to emit an optical signal. For example, the stream of electrons may be directed through the corresponding electron aperture 191 into a corresponding the gain region 160 of the VCSEL 150, which may cause a lasing process to produce and emit an optical signal from the beam aperture 190 of the VCSEL 150. The optical signal may have a wavelength determined by properties and/or configuration (e.g., size, shape, design, etc.) of the laser, including the reflectivity of the top mirror 180 and the bottom mirror 181, as well as the size and material of each layer 180, 181, 170, 171, and 160 (shown in FIG. 1). In some embodiments, the optical signal may be a high bandwidth light pulse. As such, each activation of the low voltage election emission device 110 may cause a single light pulse to be emitted from the VCSEL 150. In some embodiments, the control device of the low voltage electron emission device 110 may determine a pulse width and a pulse frequency for each light pulse emitted by the VCSEL 150. Additionally or alternatively, the pulse width and pulse frequency may be predetermined values based on a particular application for which the VCSEL 150 is being used.

The method 400 may include additional embodiments, such as any single embodiment or any combination of embodiments described below and/or in connection with one or more other methods described elsewhere herein. Although FIG. 5 shows example blocks of the method 400, in some embodiments, the method 400 may include additional blocks, fewer blocks, different blocks, or differently arranged blocks than those depicted in FIG. 5. Additionally, or alternatively, two or more of the blocks of the method 400 may be performed in parallel.

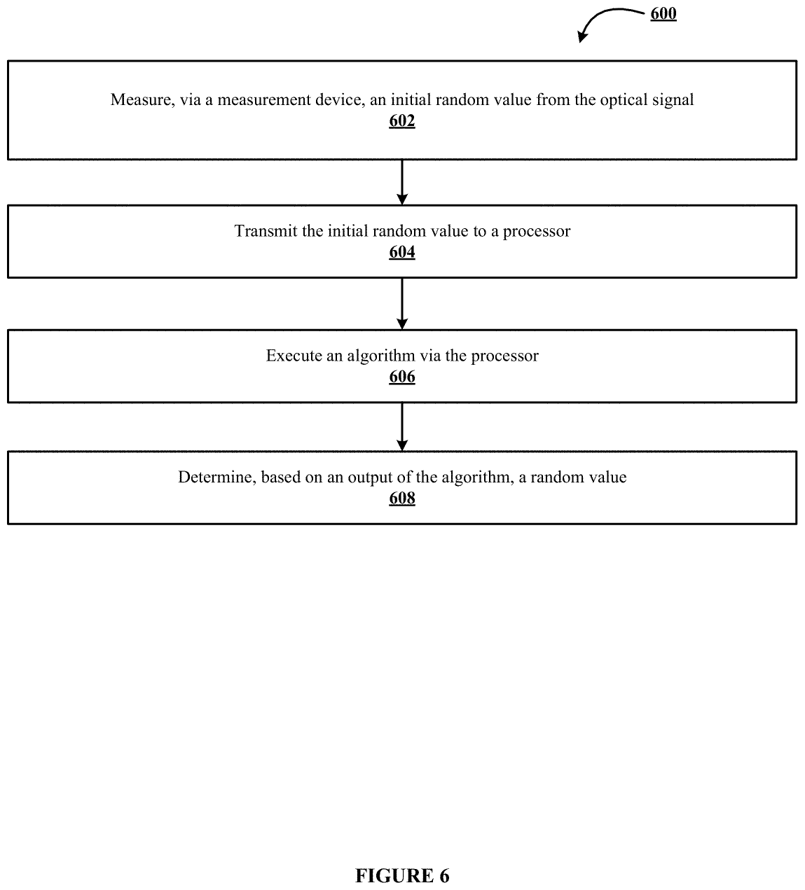

FIG. 6 illustrates a method 500 for random number generation, in accordance with an embodiment of the invention. The method may begin at block 502, wherein the system 300 (shown in FIG. 4) may measure, via the measurement device 330, an initial random value from the stream of electrons and/or from the resulting optical signal. In some embodiments, the system 300 may measure the initial random value in response to a control signal from the control device or the processor 310. The initial random value may comprise a single, discrete value (e.g., a timestamp, temperature, photon location, and/or the like) or may comprise an aggregated value based on a plurality of variables (e.g., a rate of temperature change, standard deviation of optical noise, and/or the like). In some embodiments, the measurement device 330 may measure a timestamp associated with a photon. In some embodiments, the measurement device 330 may only measure timestamps associated with photons having an intensity above a predetermined threshold value.

The method may then continue to block 504, wherein the initial random value is transmitted to the processor 310. In some embodiments, wherein the measurement device 330 is a fully integrated component of the processor 310, the initial random value may be directly accessed by the processor 310 rather than transmitted across a communication channel. In other embodiments, each random initial value may be individually transmitted to the processor 310. Additionally or alternatively, the processor 310 may receive a continuous stream of random initial values or may receive data packets, wherein each data packet contains a plurality of random initial values.

The method may then continue to block 506, wherein the processor 310 may execute a random number generation algorithm, using at least one initial random value as an input into the algorithm. A variety of algorithms may be used, such as a cryptographic hash function, a noise amplifier, and/or the like. In some embodiments, the algorithm may be a known true random number generating (TRNG) algorithm. As shown in block 508, the system may then determine, based on an output of the algorithm, a final random value. The final random value may comprise a nonce, a cryptographic key, a numeric value, a hash string, or a string value depending on a specific application of the random number generator. For example, a random number generating system that is meant to produce strong passwords may be configured to output string values, while a system that is meant to aid in data encryption may be configured to output cryptographic keys. Additionally or alternatively, the processor 310 may not perform any data processing on the initial random value and instead may output the initial random value as the final random value.

The method 500 may include additional embodiments, such as any single embodiment or any combination of embodiments described above and/or in connection with one or more other processes and methods described elsewhere herein. Although FIG. 6 shows example blocks of the method 500, in some embodiments, the method 500 may include additional blocks, fewer blocks, different blocks, or differently arranged blocks than those depicted in FIG. 6. Additionally, or alternatively, two or more of the blocks of the method 500 may be performed in parallel.

Furthermore, embodiments of the present invention may take the form of a computer program product that includes a computer-readable storage medium having one or more computer-executable program code portions stored therein. As used herein, a processor, such as the processor 310 shown in FIG. 4, which may include one or more processors, may be “configured to” perform a certain function in a variety of ways, including, for example, by having one or more general-purpose circuits perform the function by executing one or more computer-executable program code portions embodied in a computer-readable medium, and/or by having one or more application-specific circuits perform the function.

It will be understood that any suitable computer-readable medium may be utilized. The computer-readable medium may include, but is not limited to, a non-transitory computer-readable medium, such as a tangible electronic, magnetic, optical, electromagnetic, infrared, and/or semiconductor system, device, and/or other apparatus. For example, in some embodiments, the non-transitory computer-readable medium includes a tangible medium such as a portable computer diskette, a hard disk, a random access memory (RAM), a read-only memory (ROM), an erasable programmable read-only memory (EPROM or Flash memory), a compact disc read-only memory (CD-ROM), and/or some other tangible optical and/or magnetic storage device. In other embodiments of the present invention, however, the computer-readable medium may be transitory, such as, for example, a propagation signal including computer-executable program code portions embodied therein.

One or more computer-executable program code portions for carrying out operations of the present invention may include object-oriented, scripted, and/or unscripted programming languages, such as, for example, Java, Perl, Smalltalk, C++, SAS, SQL, Python, Objective C, JavaScript, and/or the like. In some embodiments, the one or more computer-executable program code portions for carrying out operations of embodiments of the present invention are written in conventional procedural programming languages, such as the “C” programming languages and/or similar programming languages. The computer program code may alternatively or additionally be written in one or more multi-paradigm programming languages, such as, for example, F#.

Some embodiments of the present invention are described herein with reference to flowchart illustrations and/or block diagrams of apparatus and/or methods. It will be understood that each block included in the flowchart illustrations and/or block diagrams, and/or combinations of blocks included in the flowchart illustrations and/or block diagrams, may be implemented by one or more computer-executable program code portions. These one or more computer-executable program code portions may be provided to a processor of a general purpose computer, special purpose computer, and/or some other programmable data processing apparatus in order to produce a particular machine, such that the one or more computer-executable program code portions, that execute via the processor of the computer and/or other programmable data processing apparatus, create mechanisms for implementing the steps and/or functions represented by the flowchart(s) and/or block diagram block(s).

The one or more computer-executable program code portions may be stored in a transitory and/or non-transitory computer-readable medium (e.g., the memory 320 shown in FIG. 4) that may direct, instruct, and/or cause a computer and/or other programmable data processing apparatus to function in a particular manner, such that the computer-executable program code portions stored in the computer-readable medium produce an article of manufacture including instruction mechanisms that implement the steps and/or functions specified in the flowchart(s) and/or block diagram block(s).

The one or more computer-executable program code portions may also be loaded onto a computer and/or other programmable data processing apparatus to cause a series of operational steps to be performed on the computer and/or other programmable apparatus. In some embodiments, this produces a computer-implemented process such that the one or more computer-executable program code portions that execute on the computer and/or other programmable apparatus provide operational steps to implement the steps specified in the flowchart(s) and/or the functions specified in the block diagram block(s). Alternatively, computer-implemented steps may be combined with, and/or replaced with, operator- and/or human-implemented steps in order to carry out an embodiment of the present invention.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other changes, combinations, omissions, modifications and substitutions, in addition to those set forth in the above paragraphs, are possible. Those skilled in the art will appreciate that various adaptations, modifications, and combinations of the just described embodiments may be configured without departing from the scope and spirit of the invention. Therefore, it is to be understood that, within the scope of the appended claims, the invention may be practiced other than as specifically described herein.

What is claimed is:

1. A system for generating optical signals, comprising:
a vertical-cavity surface-emitting laser (VCSEL) configured to emit an optical signal; and
a low voltage electron emission device operatively coupled to the VCSEL and comprising an electron source, wherein, upon activation of the low voltage electron emission device, the electron source is configured to emit a stream of electrons,
wherein the VCSEL is configured to receive the stream of electrons from the low voltage electron emission device, and
wherein the VCSEL is configured to emit an optical signal in response to receipt of the stream of electrons.

2. The system of claim 1, wherein the VCSEL is one of a plurality of VCSELs, wherein the low voltage electron emission device comprises an array of electron sources, and wherein each electron source is configured to be operatively coupled to one VCSEL from the plurality of VCSELs.

3. The system of claim 1, wherein the VCSEL is one of a plurality of VCSELs, wherein the low voltage electron emission device comprises a plurality of ring-shaped arrays of electron sources, and wherein each ring-shaped array is configured to be operatively coupled to one VCSEL from the plurality of VCSELs.

4. The system of claim 1, wherein the electron source comprises a carbon nanotube.

5. The system of claim 1, wherein the low voltage electron emission device is operatively coupled to a direct current (DC) power source, and wherein the DC power source is configured to apply a voltage of less than five volts to the low voltage electron emission device to generate the stream of electrons.

6. The system of claim 1, wherein the electron source comprises a metallic tip.

7. The system of claim 1, wherein the activation of the low voltage electron emission device causes an electrical field to be applied around the electron source, causing the electron source to emit electrons.

8. The system of claim 1, wherein the low voltage electron emission device further comprises a gate configured to focus the stream of electrons into a collimated electron beam.

9. The system of claim 8, wherein the VCSEL comprises an input end and an emission end, wherein the gate is further configured to direct the electron beam into the input end of the VCSEL and wherein the optical signal is emitted from the emission end of the VCSEL.

10. The system of claim 8, wherein the VCSEL comprises an input end and an emission end, wherein the gate is further configured to operate as an external cavity resonator and wherein the optical signal is emitted from the emission end of the VCSEL.

11. The system of claim 1, further comprising a processor operatively coupled to the low voltage electron emission device, wherein the processor is configured to determine a random output value based on a measurement of an initial random value obtained from at least one of the stream of electrons or the optical signal.

12. A method of generating an optical signal, comprising the steps of:
activating a low voltage electron emission device, wherein the low voltage electron emission device comprises a electron source;
causing the electron source to emit a stream of electrons; and
directing the stream of electrons into a vertical-cavity surface-emitting laser (VCSEL), wherein the VCSEL is operatively coupled to the low voltage electron emission device,
wherein the VCSEL is configured to emit an optical signal in response to receipt of the stream of electrons.

13. The method of claim 12, wherein the VCSEL is one of a plurality of VCSELs, wherein the low voltage electron emission device comprises a plurality of ring-shaped arrays of electron sources, and wherein each ring-shaped array is configured to be operatively coupled to one VCSEL from the plurality of VCSELs.

14. The method of claim 12, wherein the VCSEL is one of a plurality of VCSELs, wherein the low voltage electron emission device comprises an array of electron sources, and wherein each electron source is configured to be operatively coupled to one VCSEL from the plurality of VCSELs.

15. The method of claim 12, wherein the electron source comprises a carbon nanotube.

16. The method of claim 10, wherein activating the low voltage electron emission device further comprises applying a voltage in the range of less than five volts of direct current (DC) power to the low voltage electron emission device.

17. The method of claim 10, wherein the electron source comprises a metallic tip.

18. The method of claim 10, wherein activating the low voltage electron emission device causes an electrical field to be applied around the electronic source, causing the electron source to emit electrons

19. The method of claim 10, further comprising collimating, via a gate, the stream of electrons into an electron beam.

20. The method of claim 19, wherein the VCSEL comprises an input end and an emission end, the method further comprising the step of directing the electron beam into the input end of the VCSEL, wherein the optical signal is emitted from the emission end of the VCSEL.

21. The method of claim 19, wherein the VCSEL comprises an input end and an emission end, wherein the gate is further configured to operate as an external cavity resonator and wherein the optical signal is emitted from the emission end of the VCSEL.

22. The method of claim 12, further comprising the steps of:
receiving, via a processor, a measurement of an initial random value obtained from at least one of the stream of electrons or the optical signal; and
determining, via the processor, a random output value based on the initial random value.

23. A system for random number generation, the system comprising:
a low voltage electron emission device comprising a carbon nanotube, wherein, upon activation of the low voltage electron emission device, the carbon nanotube is configured to emit a stream of electrons; and
a processor, wherein the processor is configured to:
receive a measurement of at least one initial random value obtained from at least one of the stream of electrons or an optical signal;
execute an algorithm, wherein at least one input of the algorithm is the at least one initial random value; and
determine, based on an output of the algorithm, a final random value.

24. The system of claim 23, further comprising a measuring device configured to obtain the measurement of the initial random value and to communicate the initial random value to the processor, wherein the measuring device comprises at least a photodiode amplifier and a clock.

25. The system of claim 23, wherein the initial random value comprises at least a timestamp associated with a photon.

26. The system of claim 23, wherein the algorithm is a true random number generating (TRNG) algorithm.

27. The system of claim 23, wherein the final random value comprises at least one of: a nonce, a cryptographic key, a numeric value, a hash string, or a string value comprising a combination of alphanumeric values.

28. The system of claim 23, further comprising a vertical-cavity surface-emitting laser (VCSEL) operatively coupled to the low voltage electron emission device, wherein the VCSEL is configured to receive the stream of electrons from the low voltage electron emission device and to emit the optical signal in response to receipt of the stream of electrons.

29. A method for random number generation, the method comprising:
activating a low voltage electron emission device, wherein the low voltage electron emission device comprises a carbon nanotube, wherein activation of the low voltage electron emission device causes the carbon nanotube to emit a stream of electrons;
measuring, via a measuring device, at least one initial random value from at least one of the stream of electrons or an optical signal;
executing an algorithm, wherein at least one input of the algorithm is the at least one initial random value; and
determining, based on an output of the algorithm, a final random value.

30. The method of claim 29, wherein the measuring device comprises at least a photodiode amplifier and a clock.

31. The method of claim 29, wherein the algorithm is a true random number generating (TRNG) algorithm.

32. The method of claim 29, wherein the final random value comprises at least one of: a nonce, a cryptographic key, a numeric value, a hash string, or a string value comprising a combination of alphanumeric values.

33. The method of claim 29, further comprising the step of directing the stream of electrons into a vertical-cavity surface-emitting laser (VCSEL) so as to cause the VCSEL to emit the optical signal.
